(19) United States
(12) Patent Application Publication
(10) Pub. No.: US 2009/0180048 A1
(43) Pub. Date: Jul. 16, 2009

(54) RECEIVING MEMBER, DISPLAY HAVING THE SAME, AND METHOD THEREOF

(75) Inventors: Yun-Nam KIM, Suwon-si (KR); Yeun-Mo YEON, Hwaseong-si (KR); Hwan-Jun SUNG, Seongnam-si (KR); Jin-Man YUN, Seongnam-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/185,883

(22) Filed: Aug. 5, 2008

(30) Foreign Application Priority Data
Jan. 15, 2008 (KR) 10-2008-0004406

(51) Int. Cl. G02F 1/1333; H05K 5/00; H01S 4/00; B28B 19/00

(52) U.S. Cl. 349/58; 264/239; 29/592.1

(57) ABSTRACT

The present invention relates to a receiving member which accommodates a display panel which displays an image. The receiving member includes an insulated body portion having a bottom plate and sidewalls to define a receiving space, and at least one ground metal portion provided at a region of the insulated body portion, the at least one ground metal portion formed integrally with the insulated body portion. Accordingly, the body portion of the receiving member is formed of an insulated material, thereby reducing the weight of the receiving member and improving heat radiation. Further, a local metal portion is provided in the receiving member, thereby improving electromagnetic interference (“EMI”) and electrostatic discharge performances of elements such as a control board.

This application claims priority to Korean Patent application No. 10-2008-0004406, filed on Jan. 15, 2008, and all the benefits accruing therefrom under 35 U.S.C. 119, the contents of which in its entirety are herein incorporated by reference.

### BACKGROUND OF THE INVENTION

1. Field of the Invention

The present invention relates to a receiving member, a display having the same, and a method thereof, and more particularly, to a receiving member having a light weight and improving characteristics of backlight assembly, a display having the receiving member, and a method of manufacturing the receiving member.

2. Description of the Related Art

A flat panel display includes a display panel having a flat panel shape and a receiving member for accommodating the display panel. The receiving member accommodates a display panel therein to fix the display panel and to protect it against external impact.

As the size of a display panel is increased, the size of a receiving member for accommodating the display panel is also increased. A conventional receiving member is formed of a metallic material such as aluminum. In this case, as the size of the receiving member is increased, the weight of the receiving member is also increased. Further, when a liquid crystal display (“LCD”) panel is used as the display panel, a plurality of lamps is disposed in an inside of a bottom plate of the receiving member to be used as a backlight. A control board is attached on an outside of the bottom plate of the metallic receiving member.

### BRIEF SUMMARY OF THE INVENTION

It is has been determined herein that a parasitic capacitance is generated between a conventional metallic receiving member and a lamp contained therein, so that a leakage current is increased. This causes characteristics (uniformity between lamps) of a plurality of lamps contained within the conventional metallic receiving member to be lowered. The conventional metallic receiving member does not shield heat from the lamps, and the heat is directly conducted to a control board attached on an outside of the bottom plate of the conventional metallic receiving member. Therefore, the temperature of the control board is increased, thereby resulting in malfunction of the control board.

The present invention provides a receiving member having a ground metal portion provided in an inside thereof and manufactured using an insulated synthetic resin so that the weight of the receiving member can be reduced, characteristics of lamps can be enhanced, and heat radiated to the outside of the receiving member can be reduced.

The present invention also provides a display having the receiving member.

The present invention also provides a method of manufacturing the receiving member.

According to exemplary embodiments of the present invention, there is provided a receiving member which accommodates a display panel which displays an image. The receiving member includes an insulated body portion having a bottom plate and sidewalls to define a receiving space, and at least one ground metal portion provided at a region of the insulated body portion, the at least one ground metal portion formed integrally with the insulated body portion.

The insulated body portion is preferably formed of an insulated synthetic resin, which may include any one of polycarbonate (PC), polyethylene terephthalate (PET), polyethylene (PE), polypropylene (PP), polystyrene (PS), acrylonitrile-butadiene-styrene (ABS) and styrene acrylonitrile copolymers (SAN).

The ground metal portion may include a ground metal plate and a contact pad.

The ground metal plate may be embedded in the bottom plate or positioned on one of outer and inner surfaces of the bottom plate.

A groove may be formed in the bottom plate and the ground metal plate may be provided in the groove, or a through-hole may be formed in the bottom plate and the ground metal plate may be provided in the through-hole.

The contact pad may include a ground protrusion protruding from the ground metal plate. The ground protrusion may be formed by bending a portion of the ground metal plate.

The ground metal plate may be embedded in the bottom plate, and the bottom plate may include an exposing groove which exposes a portion of the ground metal plate and forms the contact pad. The contact pad may further include a conductive material with which the exposing groove is filled.

The ground metal portion may be formed in a shape of a plate or thin film on the outer surface of the bottom plate, and a region of the bottom plate having the ground metal portion formed thereon may protrude in a protrusion shape, wherein the ground metal portion may be formed by a metal printing process or by attaching a metal thin film on the outer surface of the bottom plate.

An outer surface of the bottom plate may be adjacent to a control board of the display panel and a lamp power supply unit, and the at least one ground metal portion may include a first ground metal portion adapted to be connected to a ground portion of the control board and a second ground metal portion adapted to be connected to a ground portion of the lamp power supply unit, and the first and second ground metal portions may be separated from each other.

According to other exemplary embodiments of the present invention, there is provided a flat panel display, which includes a receiving member including an insulated body portion having a bottom plate and sidewalls to define a receiving space, and at least one ground metal portion positioned at a region of the insulated body portion, the at least one ground metal portion formed integrally with the insulated body portion; a lamp unit accommodated in the receiving space of the receiving member; and a display panel provided over the lamp unit.

The display may further include a control board which provides control signals to display an image on the display panel and a lamp power supply unit which supplies power to the lamp unit, the control board and the lamp power supply unit provided on an outer surface of the bottom plate, wherein ground portions of the control board and the lamp power supply unit may be connected to the ground metal portion.

The ground metal portion may include a first ground metal portion connected to the ground portion of the control board and a second ground metal portion connected to the ground portion of the lamp power supply unit. The first and second ground metal portions may be separated from each other.

The display may further include a set box which provides an image signal to the control board, wherein the ground metal portion may further include a third ground portion to which a ground portion of the set box is connected, and at least the first and third ground metal portions may be electrically connected, at least one of the first to third ground metal portions being divided into a plurality of regions.

The ground metal portion may be provided in the shape of a plate or thin film on the inner or outer surface of the bottom plate and includes ground protrusions connected to the ground portions of the control board, the lamp power supply unit and the set box.

The ground protrusion and the ground portion may be coupled to each other by a coupling member including one of a screw, hook, bolt and conductive adhesive.

A lamp holder which supports the lamp unit is preferably formed integrally with the insulated body portion on an inner surface of the bottom plate of the body portion.

The display may further include a control board which provides control signals to display an image on the display panel and a lamp power supply unit which supplies power to the lamp unit, the control board and the lamp power supply unit provided on an outer surface of the bottom plate, wherein a fixing member which fixes the control board and the lamp power supply unit to the outer surface of the bottom plate may be formed integrally with the body portion.

According to still other exemplary embodiments of the present invention, there is provided a method of manufacturing a receiving member, which includes preparing at least one ground metal plate having at least one ground protrusion formed thereon; disposing the at least one ground metal plate in a mold for forming a body portion; and manufacturing the body portion having the ground metal plate embedded therein by an injection molding of a synthetic resin, the ground protrusion protruding to an outside of the body portion, the body portion having a receiving space.

### BRIEF DESCRIPTION OF THE DRAWINGS

Exemplary embodiments of the present invention can be understood in more detail from the following description taken in conjunction with the accompanying drawings, in which:

FIG. 1 is an exploded perspective view of an exemplary display according to an exemplary embodiment of the present invention;

FIG. 2 is an assembled sectional view of the exemplary display according to the exemplary embodiment of the present invention;

FIG. 3 is an exploded perspective view illustrating an exemplary lower receiving member and elements fixed thereto according to the exemplary embodiment of the present invention;

FIG. 4 is a sectional view of the exemplary lower receiving member according to the exemplary embodiment of the present invention;

FIG. 5 is a sectional view of the exemplary lower receiving member, to which one element is connected, according to the exemplary embodiment of the present invention;

FIGS. 6 and 7 are plan views of the exemplary lower receiving members according to modifications of the exemplary embodiment; and

FIGS. 8 to 16 are sectional views of exemplary lower receiving members according to modifications of the exemplary embodiment.

### DETAILED DESCRIPTION OF THE INVENTION

Hereinafter, exemplary embodiments of the present invention will be described in detail with reference to the accompanying drawings. However, the present invention is not limited to the embodiments disclosed below but may be implemented into different forms. These embodiments are provided only for illustrative purposes and for full understanding of the scope of the present invention by those skilled in the art.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “below,” “beneath,” “lower,” “above,” “upper,” and the like, may be used herein for ease of description to describe one device or element's relationship to another device(s) or element(s) as illustrated in the drawings. It will be understood that the spatially relative terms are intended to encompass different orientations of the device in use or operation in addition to the orientation depicted in the drawings.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

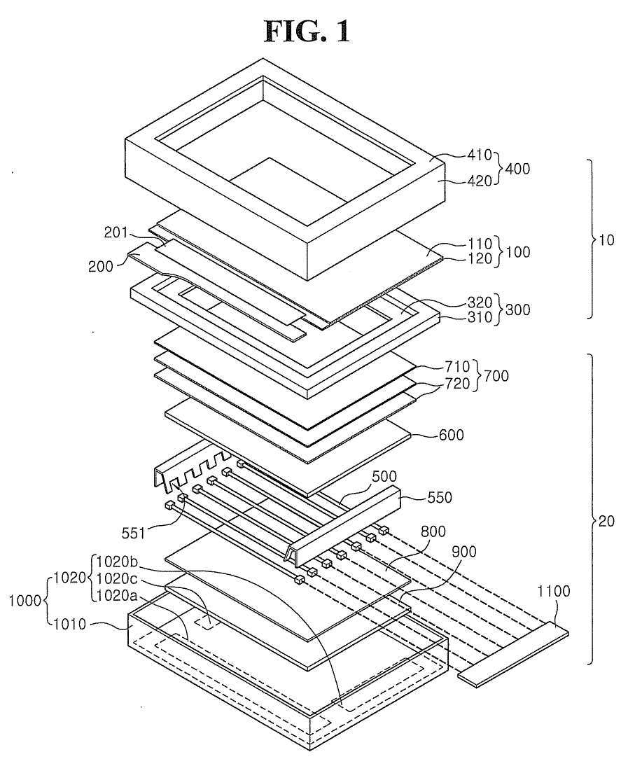

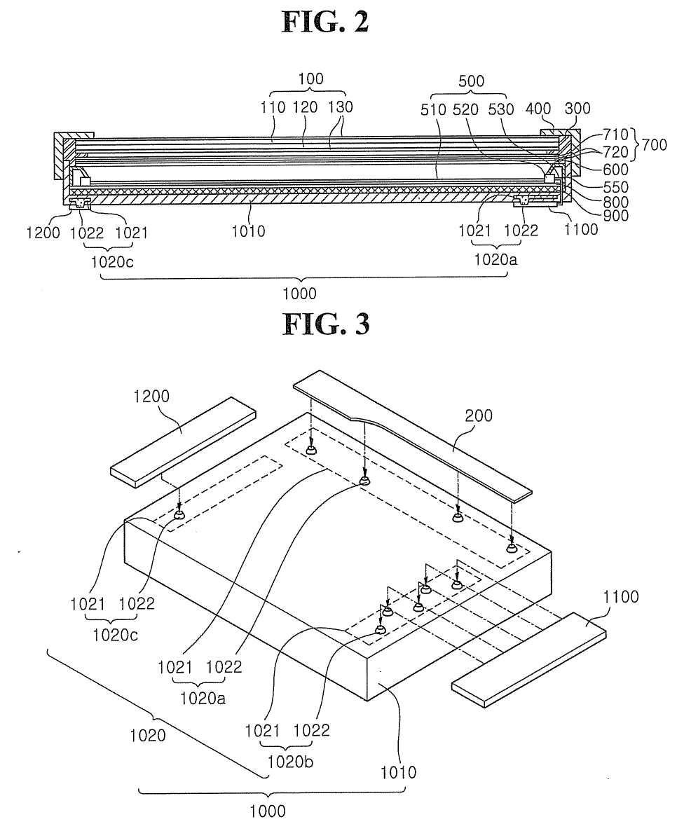

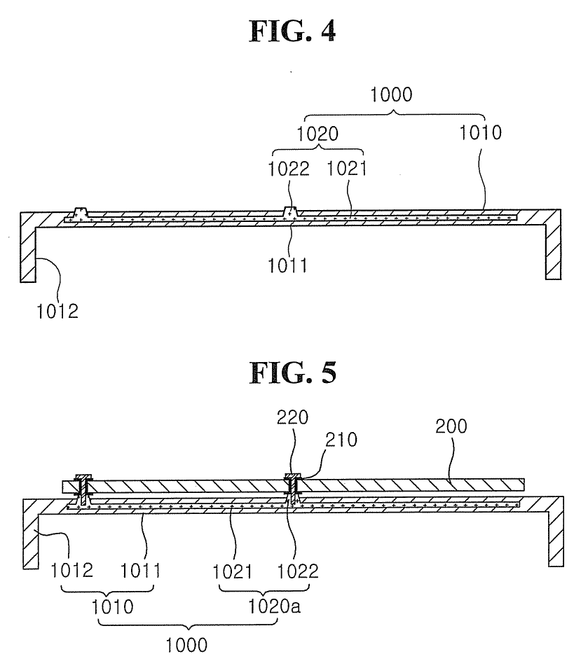

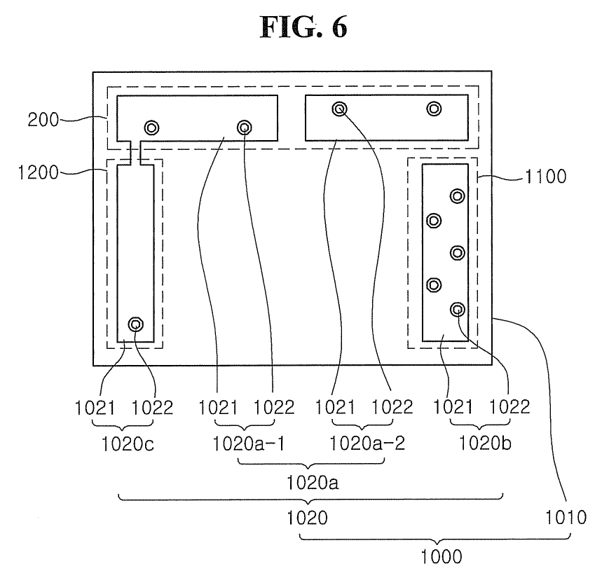

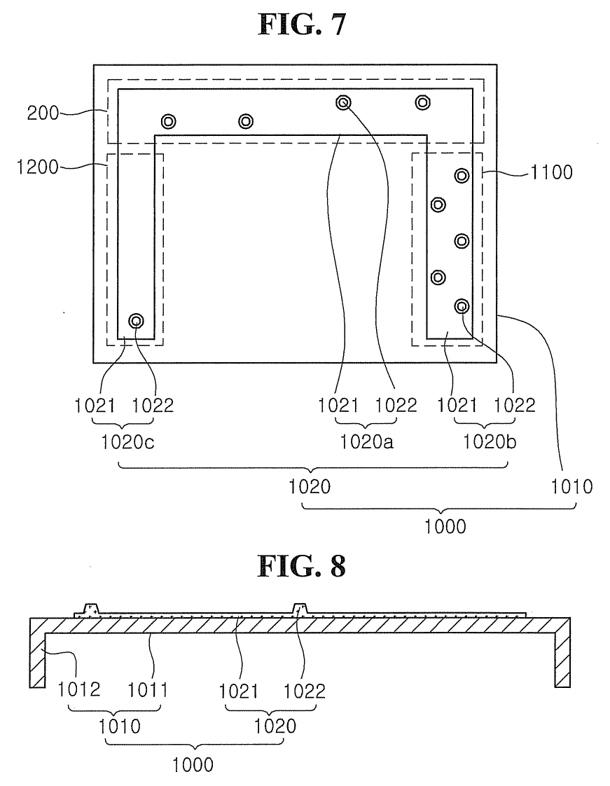

FIG. 1 is an exploded perspective view of an exemplary display according to an exemplary embodiment of the present invention, and FIG. 2 is an assembled sectional view of the exemplary display according to the exemplary embodiment of the present invention. FIG. 3 is an exploded perspective view illustrating an exemplary lower receiving member and elements fixed thereto according to the exemplary embodiment of the present invention, FIG. 4 is a sectional view of the exemplary lower receiving member according to the exemplary embodiment of the present invention, and FIG. 5 is a sectional view of the exemplary lower receiving member, to which one element is connected, according to the exemplary embodiment of the present invention. FIGS. 6 and 7 are plan views of exemplary lower receiving members according to modifications of the exemplary embodiment. FIGS. 8 to 16 are sectional views of exemplary lower receiving members according to modifications of the exemplary embodiment.

Referring to FIGS. 1 to 5, the flat panel display according to the exemplary embodiment of the present invention includes a display assembly 10 and a backlight assembly 20.

The display assembly 10 includes a liquid crystal display (“LCD”) panel 100, a control board 200, a panel supporting member 300 and an upper receiving member 400.

The LCD panel 100 includes an upper substrate 110 with color filters and a common electrode formed thereon, and a lower substrate 120 with thin film transistors (“TFTs”) and pixel electrodes formed thereon. A liquid crystal layer (not shown) is provided between the upper and lower substrates 110 and 120.

The upper substrate 110 is formed with a light shielding pattern and R, G and B color filters that are color pixels for expressing predetermined colors while light passes through the pixels. A common electrode made of a transparent conductive material, such as indium tin oxide (“ITO”) or indium zinc oxide (“IZO”), is positioned on the light shielding pattern and the color filters. In an alternative exemplary embodiment, the light shielding pattern and the color filters may be formed on the lower substrate 120.

The lower substrate 120 includes a plurality of pixel electrodes arranged in a matrix form and TFTs respectively connected to the plurality of pixel electrodes. A data line is connected to a source terminal of each of the TFTs, and a gate line is connected to a gate terminal of each of the TFTs.

If a turn-on voltage is applied to the gate line, the TFT connected to the gate line is turned on. At this time, if an image signal is applied through the data line, the pixel electrode is charged with the image signal of the data line by the turned-on TFT. Therefore, an electric field is formed between the pixel electrode of the lower substrate 120 and the common electrode of the upper substrate 110. Accordingly, the alignment of liquid crystals in the liquid crystal layer provided between the two substrates 110, 210 is changed due to the electric field. The transmittance of light is changed depending on the changed alignment of the liquid crystals, thereby obtaining a desired image.

Preferably, polarizing sheets 130 are respectively attached on a top surface of the upper substrate 110 and a bottom surface of the lower substrate 120 as shown in FIG. 2.

The control board 200 provides various signals for image expression to the LCD panel 100. The control board 200 shown in FIG. 1 is electrically connected to the lower substrate 120 through a flexible printed circuit board (“PCB”) 201. A variety of elements for driving the LCD panel 100 are mounted on the control board 200. The elements may include a voltage generator for generating an internal voltage, a grayscale voltage generator for generating a grayscale voltage, a data driver for providing image signals to the data lines, a gate driver for providing turn-on voltages to the gate lines, and a controller for controlling the operation of the voltage generator, the grayscale voltage generator and the data and gate drivers. A signal converter for converting an image signal transmitted from an external system to be suitable for the LCD panel 100 may be further mounted on the control board 200. At this time, the elements are manufactured in the form of an integrated circuit (“IC”) chip to be electrically connected to electrodes provided on the control board 200. In addition, a ground portion is provided in the control board 200 to be connected to ground terminals of the elements. The elements are not limited thereto, but some of the elements (e.g., the gate and data drivers) may be mounted on the lower substrate 120. Alternatively, the gate driver may be directly formed on the lower substrate 120. At this time, a ground terminal of the lower substrate 120 is also connected to a ground portion of the control board 200 through the flexible PCB 201.

The control board 200 is fixed to a rear surface of the flat panel display. That is, as shown in FIG. 3, the control board 200 is fixed to an outer surface of a bottom plate 1011 of a lower receiving member 1000 which will be described below. Here, the ground portion of the control board 200 is electrically connected to a ground metal portion 1020 of the lower receiving member 1000, which will also be described in detail below.

The panel supporting member 300 supports the LCD panel 100. The panel supporting member 300 is manufactured in the shape of a hollow rectangular frame. As shown in FIG. 1, the panel supporting member 300 includes a hollow frame body portion 310 and a protrusion portion 320 protruding from a lower region of an inner wall of the frame body portion 310 to the hollow thereof Here, the protrusion portion 320 supports the LCD panel 100. That is, the LCD panel 100 is seated on the protrusion portion 320. In addition, the inner wall of the frame body portion 310 (i.e., the inner wall above the protrusion portion 320), on which the protrusion portion 320 is not formed, allows a lateral side of the LCD panel 100 to be fixed. That is, the inner wall of the frame body portion 310 surrounds the lateral side of the LCD panel 100 to prevent the LCD panel 100 from playing up, down, left and right sides. Preferably, the frame body portion 310 and the protrusion portion 320 are formed in a single body. The panel supporting member 300 may be manufactured by a pressing or molding process. Preferably, the panel supporting member 300 is formed of a resin such as plastic.

The upper receiving member 400 accommodates the LCD panel 100 and the panel supporting member 300 and is coupled to the backlight assembly 20. Preferably, the upper receiving member 400 is fixedly coupled to the backlight assembly 20. The upper receiving member 400 has a plane portion 410 formed in the shape of a hollow rectangular frame and a sidewall portion 420 extending from edges of the plane portion 410. The LCD panel 100, the panel supporting member 300 and the backlight assembly 20 are accommodated in the inner space of the plane and sidewall portions 410 and 420. Accordingly, it is possible to prevent the components from escaping and to protect them against external impact. In an exemplary embodiment, the upper receiving member 400 is formed of a metal with excellent strength, light weight and less deformation. Other materials for the upper receiving member 400 would also be within the scope of these embodiments.

The backlight assembly 20 includes a lamp unit 500 for generating light; lamp fixing frames 550 for fixing the lamp unit 500; a heat shielding plate 600 and an optical film portion 700 provided over the lamp unit 500; and a reflective sheet 800 for reflecting light generated from the lamp unit 500. The backlight assembly 20 may further include a lower receiving member 1000 for accommodating the lamp unit 500, the reflective sheet 800, the lamp fixing frames 550, the heat shielding plate 600 and the optical film portion 700. In an exemplary embodiment, a heat diffusion plate 900 is provided between the lower receiving member 1000 and the lamp unit 500. In addition, the backlight assembly 20 has a lamp power supply unit 1100 for supplying power to the lamp unit 500.

As shown in FIGS. 1 and 2, the lamp unit 500 includes a plurality of lamps 510 and lamp holders 520 for respectively supporting the plurality of lamps 510. In addition, the lamp unit 500 is provided with a lamp connector 530 electrically connected to both terminals of each lamp 510. The lamp connector 530 passes through the bottom plate 1011 of the lower receiving member 1000 to be exposed to the outside. Thus, a through-hole (not shown), through which the lamp connector 530 passes, is provided at an edge region of the bottom plate 1011 of the lower receiving member 1000. As shown in FIG. 2, the lamp connector 530 is electrically connected to the lamp power supply unit 1100 provided on an outer surface of the bottom plate 1011 of the lower receiving member 1000.

Here, a cold cathode fluorescent lamp (“CCFL”) is preferably used as the lamp 510. In an alternative exemplary embodiment, an external electrode fluorescent lamp (“EEFL”) may be used as the lamp 510. The lamp unit 500 is not limited thereto but may include at least one base plate and a plurality of light emitting diodes (“LEDs”) mounted on the base plate. In FIG. 1, the lamps 510 are disposed in a major-axis direction of the flat panel display. However, the lamps 510 are not limited thereto but may be disposed in a minor-axis direction of the flat panel display.

Here, the lamp fixing frames 550 fix the lamp unit 500 to the lower receiving member 1000. To this end, each lamp fixing frame 550 has fixing grooves 551 for fixing the lamp unit 500. As shown in FIG. 1, the lamp fixing frame 550 includes an upper wall, an outer wall and an inner wall. The outer wall extends vertically from the bottom plate 1011 of the lower receiving member 1000. The inner wall is inclined with respect to the bottom plate 1011 of the lower receiving member 1000. Accordingly, the predetermined inclination given to the inner wall causes light radiating toward the inner wall to be guided toward the optical film portion 700. It is shown in FIG. 2 that the heat shielding plate 600 is supported on the upper wall of the lamp fixing frame 550. However, the heat shielding plate 600 is not limited thereto but may be fixed to a central region of the inner wall of the lamp fixing frame 550. In this case, a stepped portion on which the heat shielding plate 600 is seated may be formed on the inner wall of the lamp fixing frame 550. The outer wall of the lamp fixing frame 550 is in close contact with sidewalls 1012 of the lower receiving member 1000.

The aforementioned fixing grooves 551 are formed in the inner wall of the lamp fixing frame 550. Here, the fixing groove 551 is formed to have a shape wherein a portion of a lower region of the inner wall is concaved upward as shown in FIG. 1. The lamp holders 520 are inserted into the plurality of fixing grooves 551 to fix the lamp unit 500. In FIG. 1, the bar-shaped lamp fixing frames 550 are respectively provided at both ends of the lamps 510. That is, the lamp fixing frames 550 are positioned in two short sides of the lower receiving member 1000. However, the lamp fixing frame 550 is not limited thereto but may be formed in the shape of a rectangular frame. Thus, an edge region of the optical film portion 700 positioned over the lamp unit 500 may be disposed on the lamp fixing frame 550. The aforementioned lamp fixing frames 550 may be manufactured in a plurality of block shapes.

The aforementioned reflective sheet 800 is provided under the lamp unit 500. It will be apparent that the reflective sheet 800 may be provided in lateral side regions of the lamp unit 500. Accordingly, the reflective sheet 800 upwardly reflects light, which is emitted from the lamp unit 500 in directions (e.g., lower and lateral directions) other than an upper direction (i.e., a direction toward the optical film portion 700), and reflects the light in the upper direction.

In this exemplary embodiment, the heat diffusion plate 900 is positioned in a lower portion of the lamp unit 500. As shown in FIGS. 1 and 2, the heat diffusion plate 900 is provided under the reflective sheet 800. At this time, the heat diffusion plate 900 diffuses heat from the lamp unit 500 to prevent the heat form being concentrated. In addition, the heat diffusion plate 900 is made of a material with excellent thermal conductivity, thereby rapidly absorbing heat from the lamp unit 500 and rapidly dissipating the absorbed heat to the outside.

The heat shielding plate 600, in this exemplary embodiment, is positioned over the lamp unit 500. The heat shielding plate 600 blocks heat of the lamp unit 500 from being transferred to the optical film portion 700 and the display assembly 10 (i.e., the LCD panel 100). Accordingly, it is possible to prevent the heat of the lamp unit 500 from deteriorating the optical film portion 700 and the display assembly 10.

The optical film portion 700 is positioned over the heat shielding plate 600 and below the LCD panel 100. The optical film portion 700 may include a luminance enhancement sheet 710 and at least one diffusion sheet 720. The luminance enhancement sheet 710 allows light advancing in a direction parallel with the transmission axis of the luminance enhancement sheet 710 to be transmitted and allows light proceeding in the other directions to be reflected. The diffusion sheet 720 diffuses light so that light from the lamp unit 500 has uniform distribution in a broad range. The optical film portion 700 may further include a diffusion plate that performs the same function as the diffusion sheet 720. Alternatively, the optical film portion 700 may further include various optical sheets or optical plates for changing properties of light as necessary.

The lamp power supply unit 1100 supplies power to the lamp unit 500. The lamp power supply unit 1100 includes a PCB and a plurality of inverters mounted thereon. In FIGS. 1 and 2, the lamp power supply unit 1100 is provided at one end of the lamps 510. However, the lamp power supply unit 1100 is not limited thereto. That is, the lamp power supply unit 1100 may be provided at each of both ends of the lamps 510. The lamp power supply unit 1100 is fixed to the outer surface of the bottom plate 1011 of the lower receiving member 1000 using a fixing member. For example, a screw, adhesive or hook may be used as the fixing member.

The PCB of the lamp power supply unit 1100 includes a ground portion to which grounds of the plurality of inverters are connected. The ground portion of the PCB is electrically connected to the ground metal portion 1020 of the lower receiving member 1000.

The lower receiving member 1000 includes an insulated body portion 1010 having a receiving space and a plurality of ground metal portions 1020. In this exemplary embodiment, the plurality of ground metal portions 1020 is provided in the insulated body portion 1010.

The body portion 1010 is manufactured in the shape of a box having an open upper portion. That is, the body portion 1010 includes the bottom plate 1011 and a plurality of sidewalls 1012 vertically bent and extending from inner edges of the bottom plate 1011. The heat diffusion plate 900, the reflective sheet 800, the lamp unit 500, the lamp fixing frame 550, the heat shielding plate 600 and the optical film portion 700 are accommodated in the receiving space of the body portion 1010. Accordingly, it is possible to prevent the elements from escaping and shifting and to prevent damage due to external impact.

Preferably, the body portion 1010 is formed of an insulated synthetic resin. In an exemplary embodiment, the body portion 1010 is made of polycarbonate (“PC”). It will be apparent, however, that the body portion 1010 is not limited thereto but may be made of any one of polyethylene terephthalate (“PET”), polyethylene (“PE”), polypropylene (“PP”), polystyrene (“PS”), acrylonitrile-butadiene-styrene (“ABS”) and styrene acrylonitrile copolymers (“SAN”). As such, in this exemplary embodiment, the body portion 1010 of the lower receiving member 1000 is formed of a light synthetic resin rather than a heavy metallic material, so that the weight of the entire lower receiving member 1000 can be reduced. In addition, the lower receiving member 1000 is formed of an insulated synthetic resin to reduce parasitic capacitance between the lamps 510 and the lower receiving member 1000, thereby enhancing luminous uniformity of the lamps 510. Further, the insulated body portion 1010 may serve to block heat from the lamps 510 positioned in an inner surface region of the bottom plate 1011 of the body portion 1010. Accordingly, it is possible to prevent heat of the lamps 510, which is disposed above an inner surface of the bottom plate 1011, from being provided to the control board 200, the lamp power supply unit 1100 and a set box 1200, which are disposed on an outer surface of the bottom plate 1011 of the body portion 1010.

The ground metal portion 1020 is connected to the control board 200 and a ground portion of the lamp power supply unit 1100, which are provided on the outer surface of the bottom plate 1011 of the lower receiving member 1000. The ground metal portion 1020 is also connected to a ground of the set box 1200. As such, in this embodiment, the ground metal portion 1020 for ground of the separate external elements (the control board 200, the lamp power supply unit 1100 and the set box 1200) is provided on the body portion 1010 of the lower receiving member 1000, thereby improving electromagnetic interference (“EMI”) and electrostatic discharge performances of the elements.

Since a plurality of elements is connected to the ground metal portion 1020, as described above, the ground metal portion 1020 may be divided into a plurality of regions. That is, the ground metal portion 1020 may be divided into a first ground metal portion 1020a electrically connected to a ground of the control board 200, a second ground metal portion 1020b electrically connected to a ground of the lamp power supply unit 1100, and a third ground metal portion 1020c electrically connected to a ground of the set box 1200. It will be apparent that the ground metal portion 1020 is not limited thereto but may be divided into less or more regions than the three ground metal portions depending on the size, type, and number of elements connected to the ground metal portion 1020. That is, a plurality of ground metal portions 1020 may be provided. In another exemplary embodiment, only one ground metal portion 1020 may be provided.

As shown in FIG. 4, each of the first to third ground metal portions 1020a, 1020b and 1020c includes a ground metal plate 1021 embedded in the bottom plate 1011 of the insulated body portion 1010 and a contact pad, such as a ground protrusion 1022, protruding to the outside of the body portion 1010. The ground protrusion 1022 protrudes through the outer surface of the bottom plate 1011. The ground metal plate 1021 may be manufactured in the shape of an approximately rectangular plate as shown in FIG. 3. It will be apparent, however, that the ground metal plate 1021 is not limited thereto but may be manufactured in other shapes such as a polygonal, circular or elliptic shape. At this time, the ground metal plate 1021 has superior electric conductivity, so that various metals that can function as a ground may be used as the ground metal plate 1021. That is, the metal may include any one of lithium (Li), iron (Fe), sodium (Na), magnesium (Mg), aluminum (Al), calcium (Ca), titanium (Ti), chromium (Cr), manganese (Mn), cobalt (Co), nickel (Ni), copper (Cu), zinc (Zn), arsenic (As), strontium (Sr), molybdenum (Mo), platinum (Pt), silver (Ag) and an alloy thereof Preferably, the ground metal plates 1021 of the first to third ground metal portions 1020a, 1020b and 1020c are similar in size to the elements (the control board 200, the lamp power supply unit 1100 and the set box 1200), which are positioned on the ground metal plates 1021, respectively. However, it will be apparent that the ground metal plate 1021 is not limited thereto but may be smaller or greater than the respective elements in size.

The ground protrusion 1022 protruding from the ground metal plate 1021 functions as a contact pad connected to the ground of the control board 200, the lamp power supply unit 1100 or the set box 1200, as described above. As an example, the contact between the ground protrusion 1022 of the first ground metal portion 1020a and a ground portion 210 of the control board 200 will be described as shown in FIG. 5.

In the exemplary embodiment shown in FIG. 5, the ground metal plate 1021 of the first ground metal portion 1020a is embedded in the body portion 1020, i.e., in the bottom plate 1011 of the body portion 1010, and only the ground protrusion 1022 protrudes to the outside of the body portion 1010. The control board 200 is fixed to the outer surface of the bottom plate 1011 of the body portion 1010. At this time, the control board 200 is fixed through fixing members, such as, but not limited to, bolts, screws or hooks. Here, the control board 200 may be fixed directly to the body portion 1020. In this embodiment, the body portion 1010 is manufactured of a synthetic resin having superior formability. Thus, the fixing member for fixing the control board 200 may be formed integrally with the body portion 1010. For example, hooks for fixing the control board 200 may be formed simultaneously when the body portion 1010 is formed. It will be apparent that the control board 200 is not limited thereto but may be fixed to the first ground metal portion 1020a.

In this embodiment, when the control board 200 is fixed to the outer surface of the bottom plate 1011 of the body portion 1010, the ground portion 210 of the control board 200 is brought into close contact with the ground protrusion 1022. Preferably, the ground portion 210 and the ground protrusion 1022 are coupled by means of a separate coupling member 220 so as to reinforce the connection between the ground portion 210 of the control board 200 and the ground protrusion 1022. As shown in FIG. 5, a screw may be used as the coupling member 220. To this end, a predetermined through-hole may be provided in the ground portion 210 of the control board 200, and a ground electrode may be formed on upper and lower circumferential regions of the through-hole and an inner wall surface thereof. A groove corresponding to the through-hole may be formed in the ground protrusion 1022. Thus, the ground electrode formed on the lower circumferential region of the through-hole can be closely fixed to a top surface of the ground protrusion 1022 by aligning the through-hole of the ground portion 210 and the groove of the ground protrusion 1022 and then inserting a screw into the through-hole and the groove. At this time, an upper region of the ground protrusion 1022 can be electrically connected to the ground electrode formed on the lower circumferential region of the through-hole of the ground portion 210, and the ground portion 210 of the control board 200 can be electrically and mechanically connected to the ground protrusion 1022 of the first ground metal portion 1020a. In this embodiment, a plurality of ground protrusions 1022 are provided in the first ground metal portion 1020a. Therefore, there may be provided a plurality of ground portions 210 of the control board 200 corresponding to the plurality of ground protrusions 1022. At this time, the aforementioned fixing member 220 is not limited to the screw. That is, a bolt, a hook, a conductive adhesive or the like may be used as the fixing member 220.

As such, in this embodiment, only the ground protrusion 1022 of the ground metal portion 1020 protrudes to the outside of the body portion 1010 to be connected to the ground portion 210 of the control board 200, and the ground metal plate 1021 is insulated since it is embedded in the body portion 1010. As described above, the ground metal plate 1021 is not exposed, so that it is possible to prevent the ground metal plate 1021 from interfering and short-circuiting with circuit elements and metal wires of the control board 200.

In order to position the ground metal plate 1021 inside of the bottom plate 1011 of the body portion 1010 as described above, in this embodiment, the ground metal plate 1021 provided with the ground protrusion 1022 is inserted into the body portion 1010 when an injection molding process is performed to form the body portion 1010. Accordingly, the body portion 1010 can be formed integrally with the ground metal plate 1021. That is, the ground metal plate 1021 formed with the ground protrusion 1022 may be disposed in a mold when the body portion 1010 is injection molded of a synthetic resin, and the ground metal plate 1021 is then embedded in the body portion 1010 by the injection molding, thereby manufacturing the lower receiving member 1000.

The configuration of the lower receiving member 1000 is not limited to the aforementioned embodiment but may be variously modified.

In an alternative exemplary embodiment of the ground metal portion 1020, a portion of the first, second or third ground metal portions 1020a, 1020b or 1020c may be divided. In the modification of FIG. 6, the first ground metal portion 1020a maybe divided into a first ground metal region 1020a-1 and a second ground metal region 1020a-2. Here, the first and second ground metal regions 1020a-1 and 1020a-2 are both connected to the ground portions 210 of the control board 200. Therefore, the first and second ground metal regions 1020a-1 and 1020a-2 can have the same or substantially the same electric potential. As shown in FIG. 6, the first ground metal region 1020a -1 of the first ground metal portion 1020a may be connected to the third ground metal portion 1020c. Accordingly, the ground level of the ground portion of the set box 1200 connected to the third ground metal portion 1020c is the same or substantially the same as that of the ground portion of the control board 200 connected to the first ground metal portion 1020a. Other connection or separations between the first, second, and third ground metal portions 1020a, 1020b, and 1020c would also be within the scope of these embodiments.

As shown in the modification of FIG. 7, the first, second, and third ground metal portions 1020a, 1020b and 1020c may be formed in a single ground metal plate 1021. Accordingly, the electric potentials of the first to third ground metal portions 1020a, 1020b and 1020c can be equally maintained.

As shown in the modification of FIG. 8, the ground metal plate 1021 of the ground metal portion 1020 is not embedded in the body portion 1010 but may instead be attached on the outer surface of the bottom plate 1011 of the body portion 1010. That is, the ground metal portion 1020 is manufactured by forming the body portion 1010 by an injection molding process and then fixing a plurality of ground metal plates 1021 having ground protrusions 1022 to the outer surface of the bottom plate 1011 of the body portion 1010. Accordingly, the lower receiving member 1000 with the body portion 1010 fixed to the ground metal portion 1020 can be manufactured. At this time, a screw, bolt, hook or adhesive may be used to fix the ground metal plate 1021 to the bottom plate 1011.

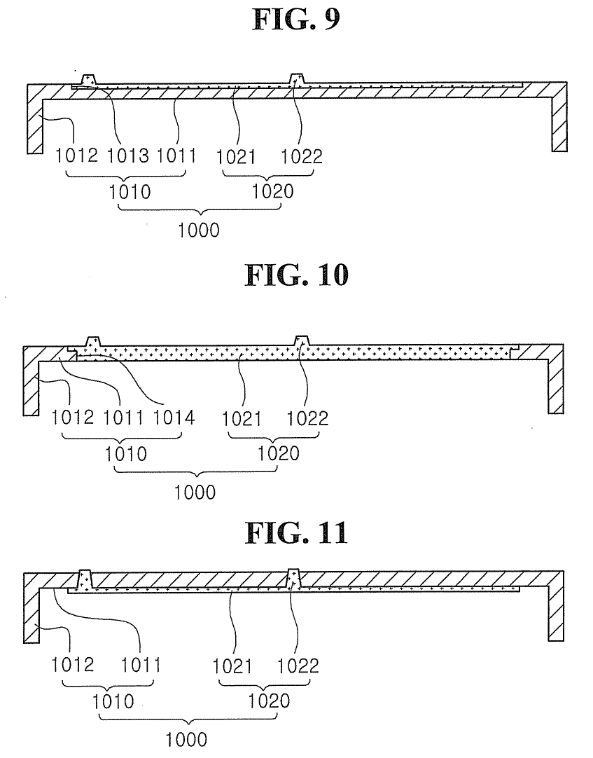

As shown in the modification of FIG. 9, as compared to the embodiment shown in FIG. 8, in order to prevent an increase in thickness of the bottom plate 1011 of the lower receiving member 1000, a groove 1013 is formed on the outer surface of the bottom plate 1011 of the body portion 1010, and the ground metal plate 1021 is inserted into the groove 1013, thereby manufacturing the lower receiving member 1000 having the ground metal portion 1020. That is, the insulated body portion 1010 with the groove 1013 formed on the outer surface of the bottom plate 1011 is manufactured such as by an injection molding process. The ground metal portion 1020 may then be manufactured by fixedly inserting the ground metal plate 1021 having ground protrusions 1022 into the groove 1013. At this time, the ground metal plate 1021 may be fixed to the body portion 1010 through a fixing member such as a screw, bolt, hook or adhesive.

As shown in the modification of FIG. 10, a through-hole 1014 is formed in the bottom plate 1011 of the body portion 1010, and the ground metal plate 1021 is inserted into the through-hole 1014, thereby manufacturing the lower receiving member 1000 having the ground metal portion 1020. In this exemplary embodiment, the ground metal plate 1021 may have a substantially same thickness as a remainder of the bottom plate 1011, but may also have a different thickness. At this time, concavo-convex patterns are preferably formed on the inner wall of the through-hole 1014 and the outer wall of the ground metal plate 1021 (i.e., the wall of the ground metal plate 1021 in contact with the inner wall of the through-hole 1014), respectively. Accordingly, the ground metal plate 1021 can be fixed in the through-hole 1014. In addition, a fixing member, such as an adhesive, may be further provided to prevent the ground metal plate 1021 from being separated from the through-hole 1014.

As shown in the modification of FIG. 11, the ground metal plate 1021 may be attached on an inner surface of the bottom plate 1011 of the body portion 1010. At this time, ground protrusions 1022 of the ground metal plate 1021 may pass through the bottom plate 1011 of the body portion 1010 to protrude to the outer surface of the bottom plate 1011 of the body portion 1010. The inner surface of the bottom plate 1011 may also include a groove, similar to groove 1013 shown in FIG. 9, so as to recess the ground metal plate 1021 into the bottom plate 1011.

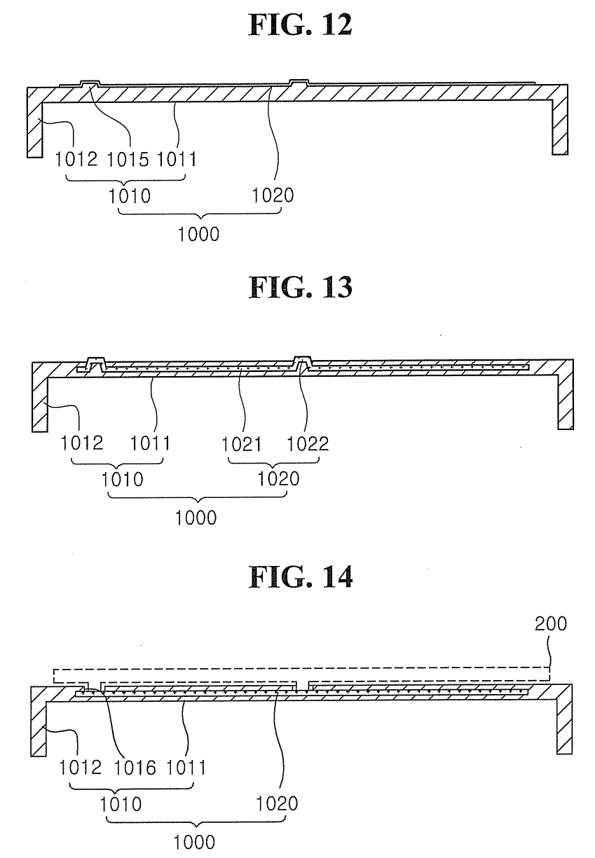

As shown in the modification of FIG. 12, the ground metal plate 1020 may be formed in a thin film shape on the outer surface of the bottom plate 1011 of the body portion 1010. At this time, protrusion portions 1015, corresponding to the ground protrusions 1022 of the aforementioned embodiments, are preferably formed on the outer surface of the bottom plate 1011 of the body portion 1010. Accordingly, the thin-film-shaped ground metal plate 1020 formed on the protrusion portions 1015 can be connected to the ground portion 210 of the control board 200. The thin-film-shaped ground metal plate 1020 may be manufactured by forming a metal thin film on the outer surface of the bottom plate 1011 of the body portion 1010 by a printing process. Alternatively, the ground metal plate 1020 may be formed by a metal thin film deposition process. Alternatively, the ground metal plate 1020 may be formed by attaching a metallic thin film on the outer surface of the bottom plate 1011 of the body portion 1010.

As shown in the modification of FIG. 13, ground protrusions 1022 of the ground metal plate 1020 may be manufactured by protruding a portion of the ground metal plate 1021. That is, the ground protrusions 1022 may be manufactured by bending a portion of the ground metal plate 1020. In this exemplary embodiment, the ground metal plate 1020 may be formed within the bottom plate 1011, similar to the embodiment shown in FIG. 4.

As shown in the modification of FIG. 14, the ground metal plate 1020 formed in a plate shape may be embedded in the body portion 1010. In addition, a plurality of exposing grooves 1016 for exposing the ground metal portion 1020 may be provided in the outer surface of the bottom plate 1011 of the body portion 1010. Accordingly, ground protrusions 1022 need not be manufactured. At this time, the ground portions 210 of the various types of members such as the control board 200 are preferably formed in a protruding shape. Thus, the protruding shaped ground portion 210 is inserted into the exposing groove 1015 to be electrically connected to the ground metal portion 1020 exposed through the exposing groove 1016.

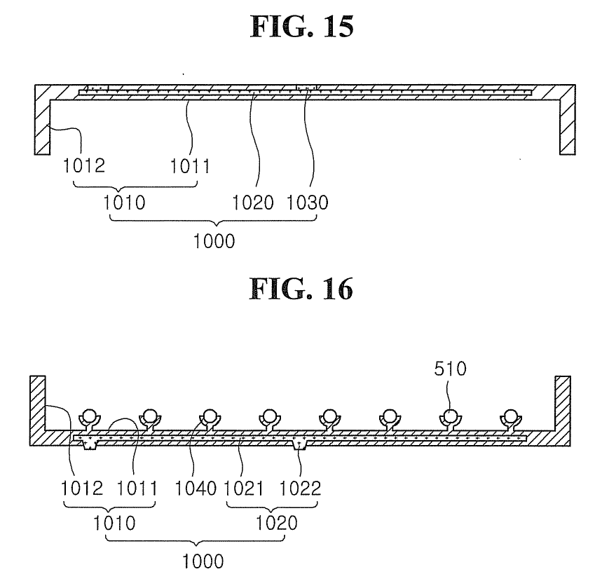

As shown in the modification of FIG. 15, a ground contact 1030 may be formed by filling the exposing grooves 1016 with a conductive material. The ground portion of the control board 200 may be electrically connected to the ground metal portion 1020 through the ground contact 1030.

While various embodiments of the ground metal portion 1020 and the body portion 1010 have been shown and described, it should be understood that combinations of the above-described embodiments and other alternative exemplary embodiments are also within the scope of these embodiments.

As shown in the modification of FIG. 16, lamp supporting holders 1040 for supporting lamps 510 may be formed on the inner surface of the bottom plate 1011 of the body portion 1010. Since the body portion 1010 of this embodiment is formed of a synthetic resin having superior formability, the lamp supporting holders 1040 may be formed together when the body portion 1010 is manufactured. That is, the lamp supporting holders 1040 may be formed integrally with the body portion 1010. Accordingly, the number of components for manufacturing a display can be reduced, and time for assembling the components can be saved, thereby reducing manufacturing time of the display.

Although not shown, the aforementioned ground metal portion 1020 may be manufactured to have a multi-layered electrode plate structure.

The display assembly 10 of the aforementioned embodiment has been described as including the LCD panel 100. However, a plasma display panel (“PDP”), an active matrix organic light emitting diode (“AM-OLED”) or the like may be used instead of the LCD panel 100. Also, although a direct-type backlight assembly 20 having a plurality of lamps 510 uniformly arranged below the LCD panel 100 has been described in the aforementioned embodiment, the present invention is not limited thereto. That is, the present invention can be applied to an edge-type backlight assembly using a light guide plate. In addition, a light source unit except the lower receiving member may be omitted depending on the used panel.

As described above, according to the embodiments of the present invention, a receiving member is formed of an insulated synthetic resin, so that it is possible to reduce the weight of the receiving member and to prevent control elements being deteriorated by internal heat of the receiving member transferred to the control elements.

Further, ground metal portions are locally formed at regions of the receiving member corresponding to the control elements such as a control board fixed to the receiving member, thereby improving EMI and ESD performances of the control elements.

Furthermore, the receiving member is formed of an insulated material to prevent occurrence of parasitic capacitance between the receiving member and lamps, thereby shielding leakage current of the lamps. Accordingly, luminance uniformity between the lamps can be enhanced.

Although the present invention has been described in connection with the accompanying drawings and exemplary embodiments, the present invention is not limited thereto but defined by the appended claims. Accordingly, it will be understood by those skilled in the art that various modifications and changes can be made thereto without departing from the spirit and scope of the invention defined by the appended claims.

What is claimed is:

1. A receiving member which accommodates a display panel displaying an image, the receiving member comprising:
an insulated body portion having a bottom plate and sidewalls to define a receiving space; and
at least one ground metal portion provided at a region of the insulated body portion, the at least one ground metal portion formed integrally with the insulated body portion.

2. The receiving member as claimed in claim 1, wherein the insulated body portion is formed of an insulated synthetic resin.

3. The receiving member as claimed in claim 2, wherein the synthetic resin comprises any one of polycarbonate (PC), polyethylene terephthalate (PET), polyethylene (PE), polypropylene (PP), polystyrene (PS), acrylonitrile-butadiene-styrene (ABS) and styrene acrylonitrile copolymers (SAN).

4. The receiving member as claimed in claim 1, wherein the ground metal portion includes a ground metal plate and a contact pad.

5. The receiving member as claimed in claim 4, wherein the ground metal plate is embedded in the bottom plate or positioned on one of an outer surface and an inner surface of the bottom plate.

6. The receiving member as claimed in claim 4, wherein a groove is formed in the bottom plate and the ground metal plate is provided in the groove, or a through-hole is formed in the bottom plate and the ground metal plate is provided in the through-hole.

7. The receiving member as claimed in claim 4, wherein the contact pad includes a ground protrusion protruding from the ground metal plate.

8. The receiving member as claimed in claim 7, wherein the ground protrusion is formed by bending a portion of the ground metal plate.

9. The receiving member as claimed in claim 4, wherein the ground metal plate is embedded in the bottom plate, and the bottom plate includes an exposing groove for exposing a portion of the ground metal plate and forming the contact pad.

10. The receiving member as claimed in claim 9, wherein the contact pad further includes a conductive material with which the exposing groove is filled.

11. The receiving member as claimed in claim 1, wherein the ground metal portion is formed in a shape of a plate or thin film on an outer surface of the bottom plate, and a region of the bottom plate having the ground metal portion formed thereon protrudes in a protrusion shape, the ground metal portion formed by a metal printing process or by attaching a metal thin film on the outer surface of the bottom plate.

12. The receiving member of claim 1, wherein an outer surface of the bottom plate is adjacent to a control board of the display panel and a lamp power supply unit, and the at least one ground metal portion includes a first ground metal portion adapted to be connected to a ground portion of the control board and a second ground metal portion adapted to be connected to a ground portion of the lamp power supply unit, the first and second ground metal portions separated from each other.

13. A display, comprising:
a receiving member including an insulated body portion having a bottom plate and sidewalls to define a receiving space, and at least one ground metal portion positioned at a region of the insulated body portion, the at least one ground metal portion formed integrally with the insulated body portion;
a lamp unit accommodated in the receiving space of the receiving member; and
a display panel provided over the lamp unit.

14. The display as claimed in claim 13, further comprising:
a control board which provides control signals to display an image on the display panel and a lamp power supply unit which supplies power to the lamp unit, the control board and the lamp power supply unit provided on an outer surface of the bottom plate,
wherein ground portions of the control board and the lamp power supply unit are connected to the ground metal portion.

15. The display as claimed in claim 14, wherein the ground metal portion includes a first ground metal portion connected to the ground portion of the control board and a second ground metal portion connected to the ground portion of the lamp power supply unit, the first and second ground metal portions separated from each other.

16. The display as claimed in claim 15, further comprising a set box which provides an image signal to the control board,
wherein the ground metal portion further includes a third ground portion to which a ground portion of the set box is connected, and at least the first and third ground metal portions are electrically connected to each other, at least one of the first to third ground metal portions being divided into a plurality of regions.

17. The display as claimed in claim 16, wherein the ground metal portion is provided in a shape of a plate or thin film on an inner surface or the outer surface of the bottom plate and includes ground protrusions connected to the ground portions of the control board, the lamp power supply unit and the set box.

18. The display as claimed in claim 17, wherein the ground protrusion and the ground portion are coupled to each other by a coupling member including one of a screw, hook, bolt and conductive adhesive.

19. The display as claimed in claim 13, wherein a lamp holder which supports the lamp unit is formed integrally with the insulated body portion on an inner surface of the bottom plate of the body portion.

20. The display as claimed in claim 13, further comprising:
a control board which provides control signals to display an image on the display panel and a lamp power supply unit which supplies power to the lamp unit, the control board and the lamp power supply unit provided on an outer surface of the bottom plate,
wherein a fixing member which fixes the control board and the lamp power supply unit to the outer surface of the bottom plate is formed integrally with the body portion.

21. A method of manufacturing a receiving member which accommodates a display panel which displays an image, the method comprising:
preparing at least one ground metal plate having at least one ground protrusion formed thereon;
disposing the at least one ground metal plate in a mold to form a body portion; and
manufacturing the body portion having the ground metal plate embedded therein by an injection molding of a synthetic resin, the ground protrusion protruding to an outside of the body portion, the body portion having a receiving space.
